(19) United States
(12) Patent Application Publication
(10) Pub. No.: US 2014/0097476 A1
(43) Pub. Date: Apr. 10, 2014

(54) SOLID-STATE IMAGING APPARATUS AND ELECTRONIC APPARATUS

(71) Applicant: Sony Corporation, Tokyo (JP)

(72) Inventor: Yoshiaki Kikuchi, Kanagawa (JP)

(73) Assignee: Sony Corporation, Tokyo (JP)

(21) Appl. No.: 14/030,312

(22) Filed: Sep. 18, 2013

(30) Foreign Application Priority Data
Oct. 9, 2012 (JP) 2012-223854

(51) Int. Cl. H01L 27/148

(52) U.S. Cl. CPC H01L 27/14812
USPC 257/229

(57) ABSTRACT

A solid-state imaging apparatus includes a charge accumulation unit, a signal voltage detection unit, a transfer transistor, and a pinning layer. The charge accumulation unit accumulates photoelectrically converted charges, and is formed on a silicon substrate. The signal voltage detection unit detects signal voltage corresponding to the charges accumulated in the charge accumulation unit, and is formed on the silicon substrate. The transfer transistor transfers the charges accumulated in the charge accumulation unit to the signal voltage detection unit, and is formed on the silicon substrate. The pinning layer pins a surface of the silicon substrate so that the surface is filled with electron holes, and is formed directly on the silicon substrate at a gate end at which a gate electrode of the transfer transistor and the charge accumulation unit come into contact with each other on the silicon substrate.

### CROSS REFERENCE TO RELATED APPLICATIONS

This application claims the benefit of Japanese Priority Patent Application JP 2012-223854 filed Oct. 9, 2012, the entire contents of which are incorporated herein by reference.

### BACKGROUND

The present disclosure relates to a solid-state imaging apparatus and an electronic apparatus, and particularly to a solid-state imaging apparatus and an electronic apparatus, which are capable of reducing a dark current while maintaining favorable transfer properties.

As a solid-state imaging apparatus, an amplifying type solid-state imaging apparatus typified by a MOS image sensor such as a CMOS (Complementary Metal Oxide Semiconductor) has been known. Moreover, a charge transfer type solid-state imaging apparatus typified by a CCD (Charge Coupled Device) image sensor has also been known.

These solid-state imaging apparatuses have been widely used in a digital still camera, a digital video camera, or the like. In recent years, as a solid-state imaging apparatus installed in a mobile apparatus such as a camera-equipped mobile phone and a PDA (Personal Digital Assistant), a CMOS images sensor, which has a low power supply voltage, is often used from a viewpoint of power consumption.

In general, a solid-state imaging apparatus receives incident light from a light-receiving surface by a light-receiving element including a photodiode, which is a main portion of a sensor unit (light-receiving unit), or the like, photoelectrically converts the light, detects a generated charge by a detection circuit, amplifies the charge after that, and output the amplified charge sequentially.

As a configuration example of a solid-state imaging apparatus, a sensor unit (light-receiving unit), which includes a charge accumulation layer (hereinafter, referred to as a first sensor region) formed by ion-implantation of a first conductive type impurity into a second conductive type semiconductor layer, and in which a p-type impurity (p-type well) serving as the second conductive type semiconductor layer is formed on an n-type silicon substrate (first conductive type semiconductor substrate), is formed. A signal charge obtained by receiving light and photoelectrically converting the light is accumulated on the charge accumulation layer.

It has been known that in a solid-state imaging apparatus, a crystal defect in a photodiode or an interface state of an interface between a photodiode and an upper layer thereof, i.e., insulating film, is the source of a dark current. As a method of preventing generation of a dark current due to the interface state, for example, a buried type photodiode structure and a HAD (Hole-Accumulation Diode) structure have been known.

In the HAD structure, a first conductive type (e.g., n-type) semiconductor area (hereinafter, referred to as n-type semiconductor area) is formed, and a second conductive type (p-type, in contrast with the previous example) shallow semiconductor area (hereinafter, referred to as p-type semiconductor area) for reducing a dark current, which has high impurity concentration, is formed in the vicinity of the surface of the n-type semiconductor area, i.e., interface between the n-type semiconductor area and an insulating film.

Specifically, in the HAD structure described above, surplus electrons are pinned by injecting a p-type impurity into the surface of the sensor unit. With the HAD structure, it is possible to reduce white spots and a dark current.

In a method of producing the HAD structure, generally, the p-type semiconductor area is formed in the vicinity of the interface between the insulating film and the n-type semiconductor area constituting a photodiode by ion-implanting boron B or boron fluoride (boron dibromide) BF2, which is a p-type impurity, and applying an annealing process (heat treatment).

In a solid-state imaging apparatus using the HAD structure for a sensor unit (photoelectric conversion area), however, profile design of making an n-type signal charge accumulation layer being a portion where a signal charge on the side of the surface of the semiconductor substrate having the HAD structure is accumulated shallow is necessary to completely transfer a signal charge to an FD (Floating Diffusion). This is because the transfer efficiency decreases if the signal charge accumulation layer is formed at a deep position of the semiconductor substrate because a channel (charge transfer path) is formed on the surface of the substrate by a gate of a transfer transistor. Therefore, it is desirable to form the signal charge accumulation layer at the shallowest possible portion of the substrate.

In view of the above, a method of forming a pinning layer on a photodiode after a side wall is formed has been also proposed.

### SUMMARY

In an accumulation layer being a p-type semiconductor area of a gate end, however, profile design of an impurity taking into account of a trade-off of a dark current and transfer properties is important.

In the case where ion-implantation is used, the p-type semiconductor area increases in depth due to the injection energy, and therefore the n-type semiconductor area being a source moves away from the gate in the depth direction, thereby degrading the transfer properties.

In the case where transfer properties are prioritized, it is necessary to provide an offset between the n-type semiconductor area and the p-type semiconductor area. However, because it is necessary to perform ion-implantation for the n-type semiconductor area prior to the gate formation, the variability in the offset amount due to deviation increases, thereby decreasing the margin of the transfer properties.

The present disclosure is made in view of the above circumstances. It is desirable to reduce a dark current while maintaining favorable transfer properties.

According to a first embodiment of the present disclosure, there is provided a solid-state imaging apparatus, including a charge accumulation unit configured to accumulate photoelectrically converted charges, the charge accumulation unit being formed on a silicon substrate, a signal voltage detection unit configured to detect signal voltage corresponding to the charges accumulated in the charge accumulation unit, the signal voltage detection unit being formed on the silicon substrate, a transfer transistor configured to transfer the charges accumulated in the charge accumulation unit to the signal voltage detection unit, the transfer transistor being formed on the silicon substrate, and a pinning layer configured to pin a surface of the silicon substrate so that the surface is filled with electron holes, the pinning layer being formed directly on the silicon substrate at a gate end at which a gate electrode of the transfer transistor and the charge accumulation unit come into contact with each other on the silicon substrate.

The charge accumulation unit may be formed by having an n-type semiconductor area formed in the silicon substrate so as to have a first depth, and a p-type semiconductor area formed in the silicon substrate so as to have a second depth, the second depth being closer to the gate electrode than the first depth.

The n-type semiconductor area may be formed by injecting an n-type impurity ion on the silicon substrate, and the p-type semiconductor area is formed of the pinning layer.

The n-type impurity ion may be injected on the silicon substrate after the gate electrode is formed on the silicon substrate.

The solid-state imaging apparatus may further include a side wall that covers the gate electrode, in which the p-type semiconductor area may be formed by injecting an n-type impurity ion on the silicon substrate after the side wall is formed on the silicon substrate.

The pinning layer may include one of a hafnium (Hf)-based insulating film and an aluminum (Al)-based insulating film.

The pinning layer may be formed directly on the silicon substrate at the gate and on a side surface of the gate electrode.

The solid-state imaging apparatus may further include a side wall that covers the gate electrode, in which the pinning layer may be formed directly on the silicon substrate and on a side surface of the gate electrode, under the side wall having the gate end.

According to a second embodiment of the present disclosure, there is provided an electronic apparatus, including a solid-state imaging apparatus, including a charge accumulation unit configured to accumulate photoelectrically converted charges, the charge accumulation unit being formed on a silicon substrate, a signal voltage detection unit configured to detect signal voltage corresponding to the charges accumulated in the charge accumulation unit, the signal voltage detection unit being formed on the silicon substrate, a transfer transistor configured to transfer the charges accumulated in the charge accumulation unit to the signal voltage detection unit, the transfer transistor being formed on the silicon substrate, and a pinning layer configured to pin a surface of the silicon substrate so that the surface is filled with electron holes, the pinning layer being formed directly on the silicon substrate at a gate end at which a gate electrode of the transfer transistor and the charge accumulation unit come into contact with each other on the silicon substrate.

In the first and second embodiments of the present disclosure, the pinning layer is formed directly on the silicon substrate at a gate end at which a gate electrode of the transfer transistor and the charge accumulation unit come into contact with each other on the silicon substrate.

According to the present disclosure, it is possible to reduce a dark current while maintaining favorable transfer properties.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a diagram showing a configuration example of a sensor unit of an existing solid-state imaging apparatus;

FIG. 2 is a diagram showing a configuration example according to an embodiment of a sensor unit of a solid-state imaging apparatus to which the present disclosure is applied;

FIG. 3 is a diagram for explaining a method of producing the sensor unit shown in FIG. 2;

FIG. 4 is another diagram for explaining the method of producing the sensor unit shown in FIG. 2;

FIG. 5 is still another diagram for explaining the method of producing the sensor unit shown in FIG. 2;

FIG. 6 is still another diagram for explaining the method of producing the sensor unit shown in FIG. 2;

FIG. 7 is still another diagram for explaining the method of producing the sensor unit shown in FIG. 2;

FIG. 8 is still another diagram for explaining the method of producing the sensor unit shown in FIG. 2;

FIG. 9 is still another diagram for explaining the method of producing the sensor unit shown in FIG. 2;

FIG. 10 is still another diagram for explaining the method of producing the sensor unit shown in FIG. 2;

FIG. 11 is still another diagram for explaining the method of producing the sensor unit shown in FIG. 2;

FIG. 12 is still another diagram for explaining the method of producing the sensor unit shown in FIG. 2;

FIG. 13 is still another diagram for explaining the method of producing the sensor unit shown in FIG. 2;

FIG. 14 is still another diagram for explaining the method of producing the sensor unit shown in FIG. 2;

FIG. 15 is a diagram showing a configuration example according to another embodiment of a sensor unit of a solid-state imaging apparatus to which the present disclosure is applied;

FIG. 16 is a diagram showing a configuration example according to still another embodiment of a sensor unit of a solid-state imaging apparatus to which the present disclosure is applied;

FIG. 17 is a diagram showing a configuration example according to still another embodiment of a sensor unit of a solid-state imaging apparatus to which the present disclosure is applied;

FIG. 18 is a diagram showing a schematic configuration of a solid-state imaging apparatus to which the present disclosure is applied; and

FIG. 19 is a block diagram showing a configuration example of a camera apparatus serving as an electronic apparatus to which the present disclosure is applied.

### DETAILED DESCRIPTION OF EMBODIMENTS

Hereinafter, an embodiment of the present disclosure will be described with reference to the drawings.

First, programs in the existing techniques will be described.

In general, a solid-state imaging apparatus receives incident light from a light-receiving surface by a light-receiving element including a photodiode (PD), which is a main portion of a sensor unit, or the like, photoelectrically converts the light, transfers a generated charge to an FD (Floating Diffusion), detects signal voltage, amplifies the signal voltage after that, and outputs the amplified voltage sequentially.

As a configuration example of a solid-state imaging apparatus, a sensor unit which includes a signal charge accumulation layer (hereinafter, referred to as a first sensor region) formed by ion-implantation of a first conductive type impurity into a second conductive type semiconductor layer, and in which a p-type impurity (p-type well) serving as the second conductive type semiconductor layer is formed on an n-type silicon substrate (first conductive type semiconductor substrate), is formed. A signal charge obtained by receiving light and photoelectrically converting the light is accumulated on the signal charge accumulation layer.

It has been known that in a solid-state imaging apparatus, a crystal defect in a photodiode or an interface state of an interface between a photodiode and an upper layer thereof, i.e., insulating film, is the source of a dark current. As a method of preventing generation of a dark current due to the interface state, for example, a buried type photodiode structure and a HAD (Hole-Accumulation Diode) structure have been known.

In the HAD structure, a first conductive type (e.g., n-type) semiconductor area is formed, and a second conductive type (p-type, in contrast with the previous example) shallow semiconductor area for reducing a dark current, which has high impurity concentration, is formed in the vicinity of the surface of the n-type semiconductor area, i.e., interface between the n-type semiconductor area and an insulating film.

In a method of producing the HAD structure, generally, a p-type semiconductor area is formed in the vicinity of the interface between the insulating film and the n-type semiconductor area constituting a photodiode by ion-implanting boron B or boron fluoride (boron dibromide) BF2, which is a p-type impurity, and applying an annealing process (heat treatment).

In a solid-state imaging apparatus using the HAD structure for a photoelectric conversion area of a sensor unit, however, profile design of making an n-type signal charge accumulation layer being a portion where a signal charge on the side of the surface of the semiconductor substrate having the HAD structure is accumulated shallow is necessary to completely transfer a signal charge to the FD. This is because the transfer efficiency decreases if the signal charge accumulation layer is formed at a deep position of the semiconductor substrate because a channel (charge transfer path) is formed on the surface of the substrate by a gate of a transfer transistor. Therefore, it is desirable to form the signal charge accumulation layer at the shallowest possible portion of the substrate.

Specifically, at an end portion of a gate electrode of the transfer transistor, which comes into contact with the signal charge accumulation layer, or in the vicinity of an end portion of the signal charge accumulation layer (hereinafter, referred to as gate end), which comes into contact with the gate electrode of the transfer transistor, profile design of an impurity is important. Specifically, in the case where the injection amount of a p-type impurity is too small, a dark current is likely to be generated at the gate end. On the other hand, in the case where the injection amount of a p-type impurity is too large, the transfer of a charge from the HAD to the FD is affected.

Specifically, when a signal charge accumulated on the signal charge accumulation layer is read (transferred), a potential of the gate end of the signal charge accumulation layer is modulated, as a potential of a channel of a MOS transistor increases. Thus, a signal charge is read from the signal charge accumulation layer. However, in the case where a p-type semiconductor area provided for preventing generation of a dark current is present, a potential of the gate end of the signal charge accumulation layer is unlikely to be modulated by a potential of the gate electrode because a potential of the p-type semiconductor area is fixed to a standard potential. Therefore, it is difficult to completely read a signal charge.

As described above, at the gate end of the solid-state imaging apparatus, there is a need to take into account of a trade-off of a dark current and transfer properties of a signal charge.

For example, a method of providing an offset between an n-type semiconductor area and a p-type semiconductor area in order to maintain favorable transfer properties has been known.

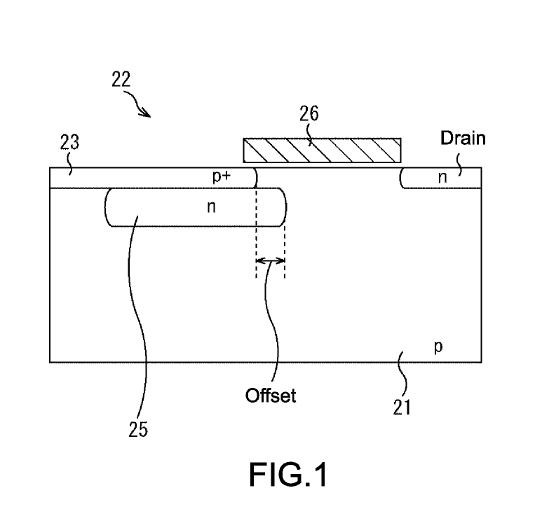

FIG. 1 is a diagram showing a configuration example of a sensor unit of a solid-state imaging apparatus in which an offset is provided between an n-type semiconductor area and a p-type semiconductor area at a gate end.

In FIG. 1, a portion where a photoelectric conversion area 22 having a HAD structure comes into contact with a gate electrode 26 of a transfer transistor is displayed. In this example, a p-type semiconductor area 23 is formed in the vicinity of a surface of a silicon substrate 21, which forms the photoelectric conversion area 22, and an n-type semiconductor area 25 is formed under the p-type semiconductor area 23.

As shown in FIG. 1, an offset is provided between the n-type semiconductor area 25, which is provided as a signal charge accumulation layer, and the p-type semiconductor area 23. Specifically, the right end portion of the n-type semiconductor area 25 is located further on the right side of the right end portion of the p-type semiconductor area 23, and extends up to below the gate electrode 26.

By providing the offset as described above, a potential of the gate end of the signal charge accumulation layer is likely to be modulated by a potential of the gate electrode 26. Accordingly, the transfer properties of a signal charge are improved.

However, in the case where such an offset is provided, there is a need to inject an-n-type impurity ion for the n-type semiconductor area 25 before the gate electrode 26 is formed on the silicon substrate 21. Therefore, a manufacturing process is complicated.

Moreover, in the case where a p-type impurity ion for the p-type semiconductor area 23 is injected and an n-type impurity ion for the n-type semiconductor area 25 is injected, there is a need to inject an ion with extremely high accuracy in order to obtain the above-mentioned offset. Actually, the transfer properties in a solid-state imaging apparatus being a completed product are not improved so much because variability in the offset amount is caused for each pixel.

In view of the above, it is desirable to reduce a dark current while improving transfer properties easily.

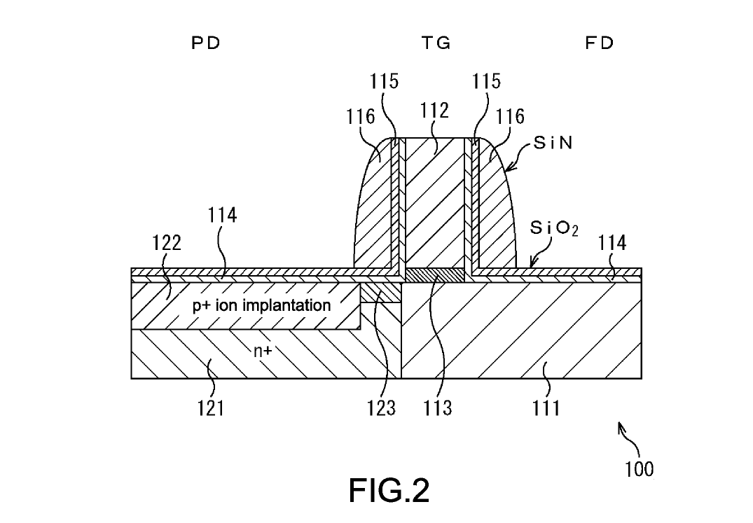

FIG. 2 is a diagram showing a configuration example according to an embodiment of a sensor unit of a solid-state imaging apparatus to which the present disclosure is applied. A sensor unit 100 shown in FIG. 2 includes a photodiode (PD), a gate electrode of a transfer transistor (TG), and a floating diffusion (FD), which are provided on a silicon substrate 111.

It should be noted that the sensor unit 100 is supposed to be used as a rear-surface irradiation type device. Therefore, actually, a light-receiving surface is displayed on the lower side of FIG. 2, and a color filter and an on-chip lens, which are not shown, are mounted thereon.

Specifically, in the sensor unit 100, an accumulated signal charge photoelectrically converted in the PD is transferred to the FD via a channel of the transfer transistor, and signal voltage is read. It should be noted that the channel of the transfer transistor is formed in the vicinity of a surface of the silicon substrate 111 under the gate electrode of the transfer transistor (TG).

The sensor unit 100 shown in FIG. 2 has a HAD structure. At the portion of the PD, an n-type semiconductor area 121 is formed, and a p-type semiconductor area 122 is formed on the n-type semiconductor area 121 to reduce a dark current. Specifically, the n-type semiconductor area 121 is formed at a deep position of the silicon substrate 111, and the p-type semiconductor area 122 is formed at a shallower position (closer position to the TG) than the n-type semiconductor area 121.

Moreover, on the right side of the PD of the sensor unit 100, a gate electrode 112 of the transfer transistor is formed. The gate electrode 112 is formed by, for example, forming a film of polysilicon (Poly-Si) so as to have a thickness of about 150 nm and performing a dry etching using patterning of photolithography. It should be noted that under the gate electrode, a gate insulating film 113 having a thickness of about 6 nm is formed.

The gate electrode 112 is covered by a pinning layer 114. The pinning layer 114 is, for example, a hafnium (Hf)-based insulating film or an aluminum (Al)-based insulating film. In the pinning layer 114, a negative fixed charge is formed. A surface of the silicon substrate 111, which comes into contact with the pinning layer 114, is fixed to be filled with electron holes.

Moreover, the gate electrode 112 is covered by a side wall. The side wall has a two-layered structure, and is formed by a first-layer side wall 115 including silicon dioxide (SiO₂) and a second-layer side wall 116 including silicon nitride (SiN).

Moreover, in the PD of the sensor unit 100 shown in FIG. 2, the position of the right end portion of the n-type semiconductor area 121 in the horizontal direction of FIG. 2, which is a signal charge accumulation layer, is almost the same as that of the left end portion of the gate electrode 112. On the other hand, the position of the right end portion of the p-type semiconductor area 122 in the horizontal direction of FIG. 2 is almost the same as that of the left end portion of the second-layer side wall 116 on the left side of the gate electrode 112.

Furthermore, in the PD of the sensor unit 100 shown in FIG. 2, on a surface of the silicon substrate 111, which comes into contact with the pinning layer 114, a pinning area 123 is formed. Here, the pinning area 123 is an area of the surface of the silicon substrate 111 fixed (pinned) to be filled with electron holes, and prevents generation of a dark current similarly to the p-type semiconductor area. The pinning area 123 can be regarded as some type of p-type semiconductor area.

The position of the right end portion of the pinning area 123 in the horizontal direction of FIG. 2 is almost the same as that of the left end portion of the gate electrode 112. This is because the pinning layer 114 is arranged along the shape of the gate electrode 112.

Specifically, at the gate end, the pinning layer 114 is formed directly on the silicon substrate 111, thereby forming an area fixed to be filled with electron holes on a surface of the silicon substrate 111 at the gate end without injecting a p-type impurity ion. Therefore, there is no need to inject a p-type impurity ion into the gate end with extremely high accuracy.

As described above, according to the present disclosure, it is possible to prevent generation of a dark current at the gate end because not only the p-type semiconductor area 122, which is formed by injecting a p-type impurity ion, but also the pinning area 123 is formed.

On the other hand, the pinning area 123 does not extend up to below the gate electrode 112, and therefore the transfer of a signal charge is not affected.

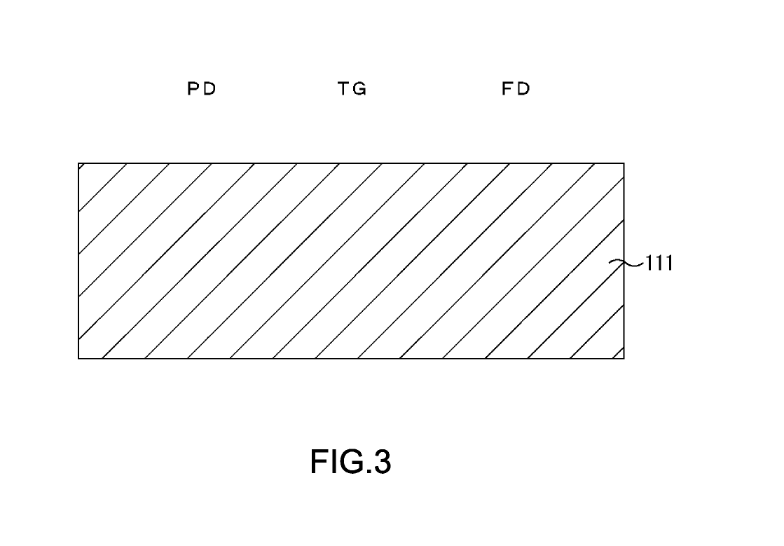

Next, a method of producing the sensor unit 100 shown in FIG. 2 will be described with reference to FIGS. 3 to 14.

First, as shown in FIG. 3, the silicon substrate 111 is produced. It should be noted that on the silicon substrate 111, the areas of PD, TG, and FD are allocated, as seen from the left side of FIG. 3.

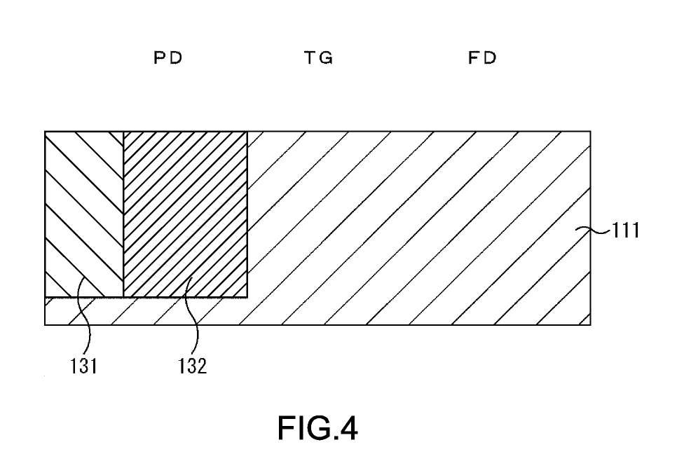

Next, as shown in FIG. 4, a separation area 131 and a photodiode area 132 are formed in the silicon substrate 111. The separation area 131 is formed by injecting a p-type impurity ion into the silicon substrate 111, and the photodiode area 132 is formed by injecting an n-type impurity ion into the silicon substrate 111.

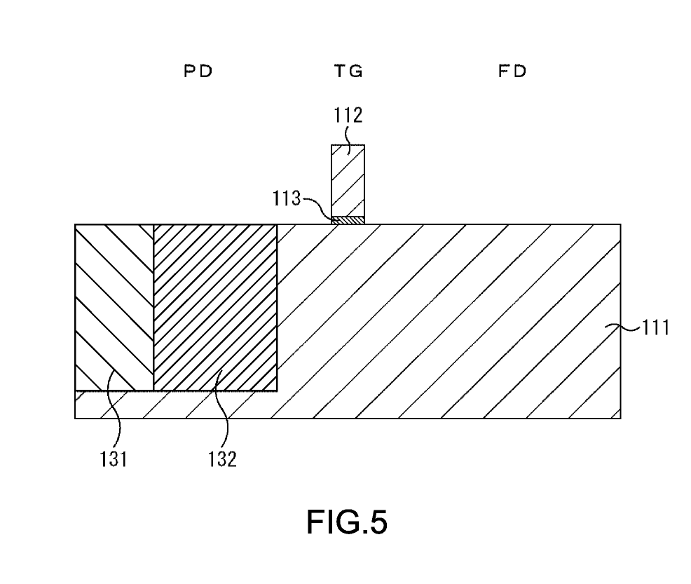

Then, as shown in FIG. 5, the gate electrode 112 is formed. After the gate insulating film 113 having a thickness of about 6 nm is formed on the silicon substrate 111, the gate electrode 112 is formed by, for example, forming a film of polysilicon (Poly-Si) so as to have a thickness of about 150 nm and performing a dry etching using patterning of photolithography.

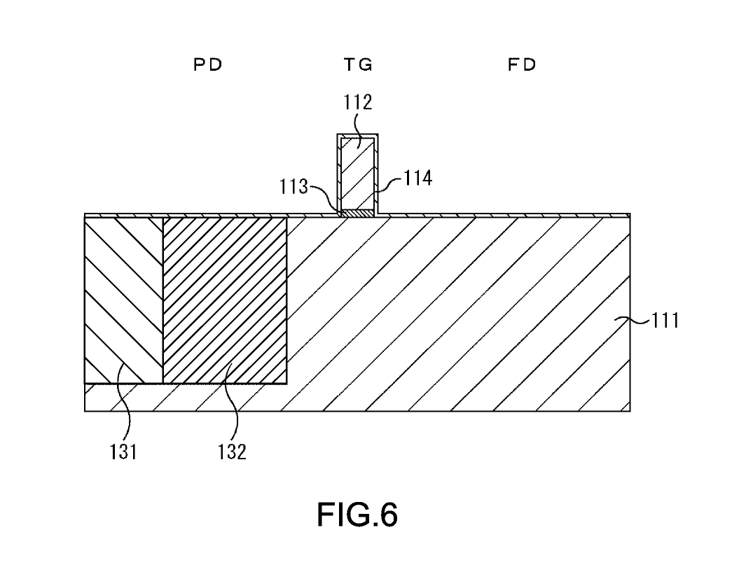

Next, as shown in FIG. 6, the pinning layer 114 is formed. The pinning layer 114 is a hafnium (Hf)-based insulating film or an aluminum (Al)-based insulating film, and a negative fixed charge is formed in the pinning layer 114.

For example, the pinning layer 114 having a thickness of 5 nm to 20 nm is formed by, for example, an ALD (Atomic Layer Deposition) method using a precursor and an ozone gas at an atmosphere temperature of about 300° C.

It should be noted that the pinning layer 114 is formed, thereby forming a pinning area fixed to be filled with electron holes on a surface of the silicon substrate 111, which comes into contact with the pinning layer 114.

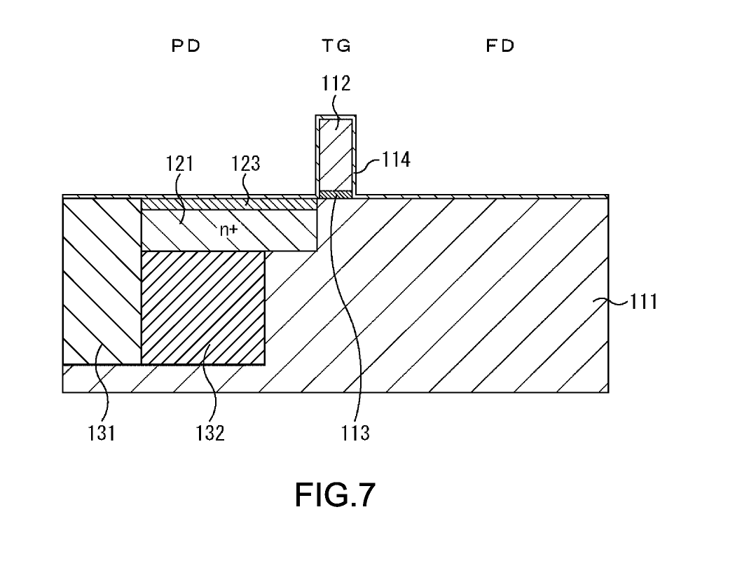

Then, as shown in FIG. 7, the n-type semiconductor area 121 is formed. At this time, an n-type impurity ion is injected into the silicon substrate 111 over the pinning layer 114. As the n-type impurity, arsenic (As), phosphorous (P), or the like is used. The injection amount of the n-type impurity ion is, for example, 1×10¹² cm², and an acceleration energy of an ion is, for example, 10 keV to 500 keV.

The n-type semiconductor area 121 is formed, thereby easily performing the transfer of a signal charge from the PD to FD via a channel under the gate electrode 112.

Moreover, the pinning area 123 is formed on the n-type semiconductor area 121.

Specifically, at the gate end, the pinning layer 114 is formed directly on the silicon substrate 111, thereby forming an area fixed to be filed with electron holes on a surface of the silicon substrate 111 without injecting a p-type impurity ion. Therefore, there is no need to inject a p-type impurity ion into the gate end with extremely high accuracy.

It should be noted that although only the pinning area 123, which is an area of the PD on the surface of the silicon substrate 111, is shown in FIG. 7, the pinning area exists also in an area of the FD on the surface of the silicon substrate 111, actually.

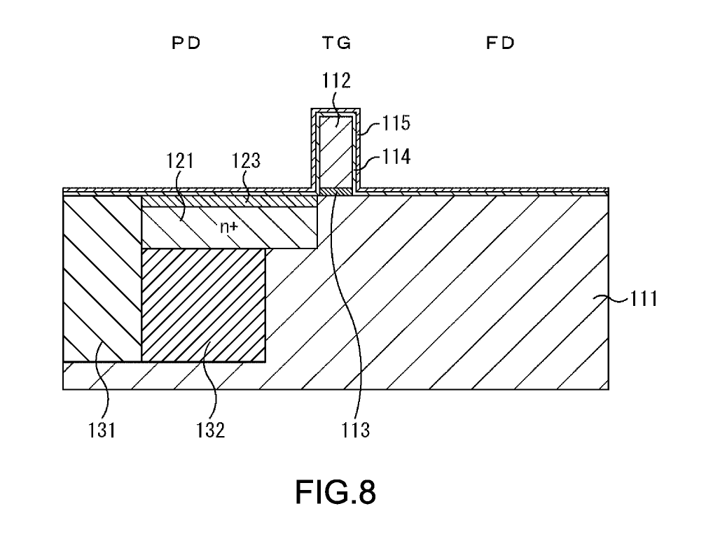

Next, as shown in FIG. 8, the first-layer side wall 115 is formed. The first-layer side wall 115 includes silicon dioxide (SiO₂) and is formed to have a thickness of about 20 nm.

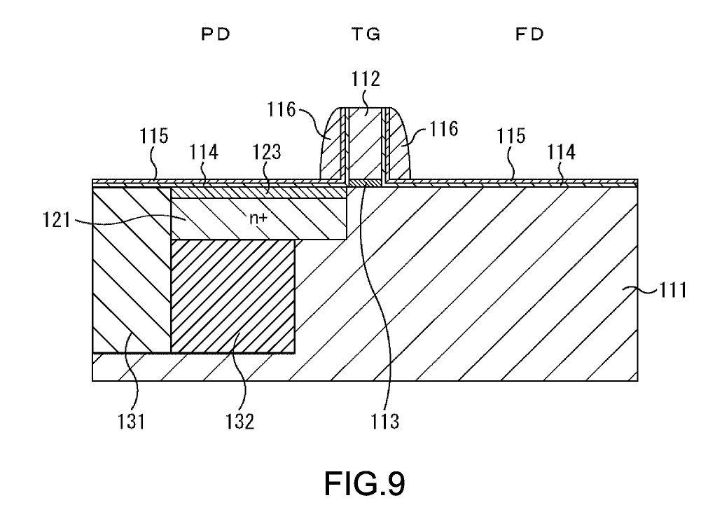

Additionally, as shown in FIG. 9, the second-layer side wall 116 is formed. The second-layer side wall 116 includes silicon nitride (SiN), and is formed by etching of an SiN film formed to have a thickness of about 50 nm.

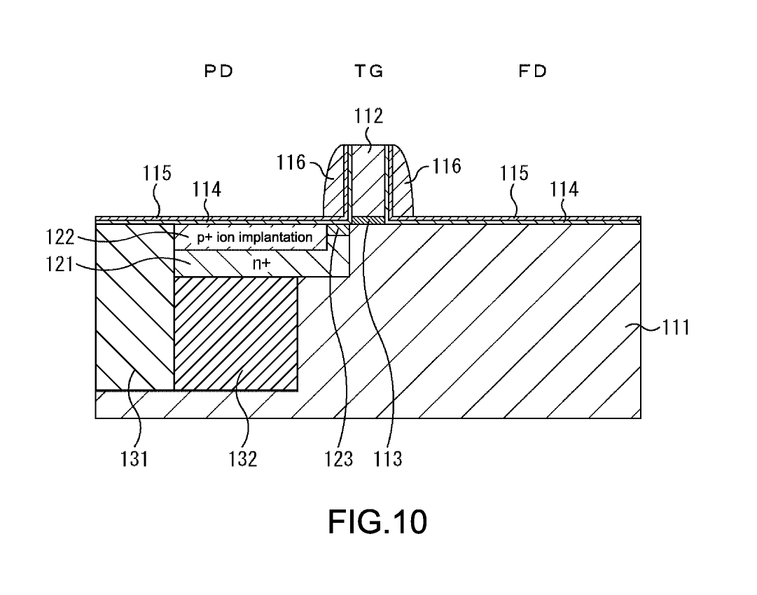

Next, as shown in FIG. 10, the p-type semiconductor area 122 is formed in the area of PD on the surface of the silicon substrate 111. At this time, a p-type impurity ion is injected into the silicon substrate 111 over the pinning layer 114 and the first-layer side wall 115. At this time, the injection amount of the p-type impurity ion is, for example, 1×10¹³ cm², and an acceleration energy of an ion is, for example, 10 keV to 100 keV.

It should be noted that since not only the p-type semiconductor area 122 but also the pinning area 123 for preventing generation of a dark current has been formed, ion-implantation for forming the p-type semiconductor area 122 does not have to be performed. It should be noted that the p-type semiconductor area 122 is favorably formed because the area of the PD on the surface of the silicon substrate 111 is considered to be damaged due to the etching at the time of forming the second-layer side wall 116.

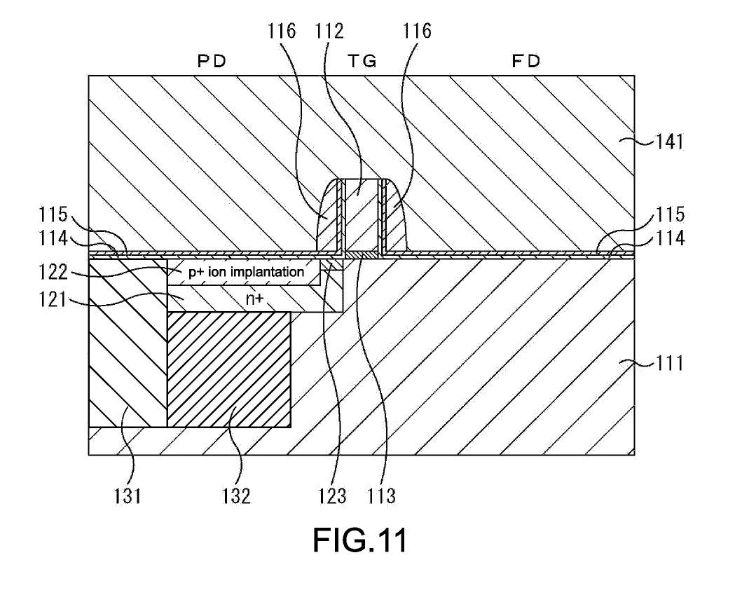

Then, as shown in FIG. 11, an interlayer film 141 is formed. At this time, for example, the interlayer film formed to have a thickness of about 500 nm is planarized by CMP (chemical mechanical polishing).

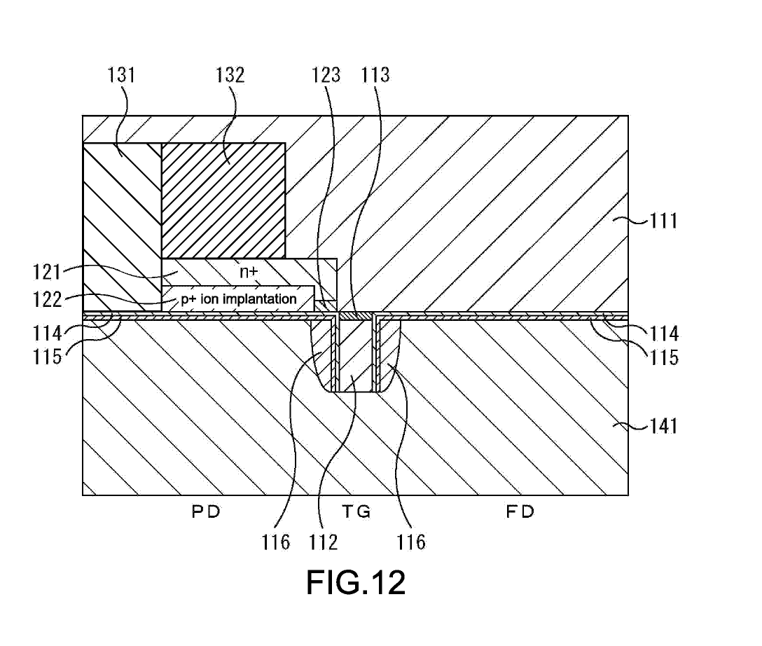

After that, as shown in FIG. 12, the silicon substrate 111 and the interlayer film 141 are inverted, and the silicon substrate 111 is planarized.

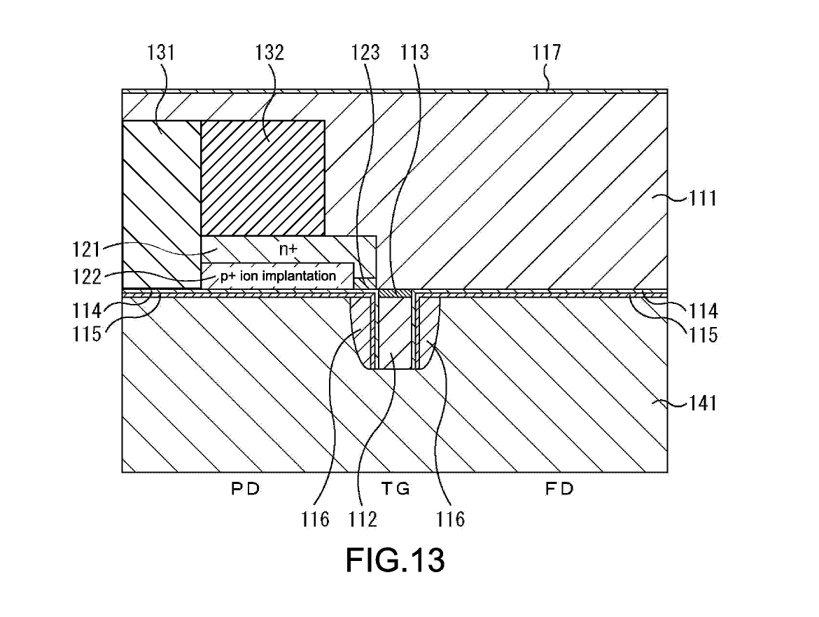

Furthermore, as shown in FIG. 13, a pinning layer 117 is formed on the upper side of the silicon substrate 111 in FIG. 13.

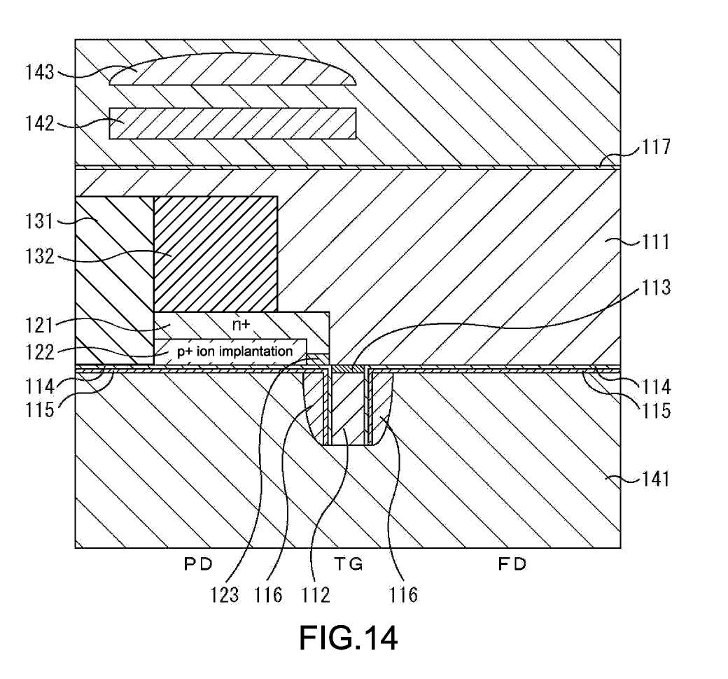

Then, as shown in FIG. 14, a color filter 142 and an on-chip lens 143 are mounted, and thus the sensor unit 100 is formed.

The sensor unit 100 is produced in this way. As described above with reference to FIG. 7, because an n-type impurity ion for forming the n-type semiconductor area 121 is injected after the gate electrode 112 is formed on the silicon substrate 111, the manufacturing process is not complicated.

Moreover, as described above with reference to FIG. 10, because a p-type impurity ion for forming the p-type semiconductor area 122 is injected after the second-layer side wall 116 is formed on the silicon substrate 111, high concentration of p-type impurity ions do not diffuse under the gate electrode 112. Specifically, the second-layer side wall 116 functions as a mask.

As described above, according to the present disclosure, it is possible to easily produce a sensor unit, which maintains the transfer properties of a signal charge while preventing generation of a dark current at a gate end.

Meanwhile, in the configuration described above with reference to FIG. 2, the pinning layer 114 extends widely on a surface of the silicon substrate 111, but the pinning layer 114 is arranged so that the pinning area 123 is formed at the gate end. Therefore, an unnecessary portion of the pinning layer 114 may be removed.

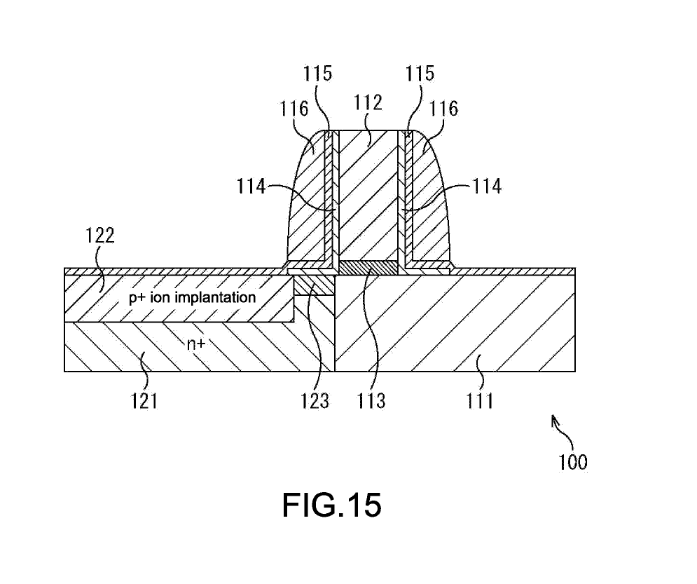

FIG. 15 is a diagram showing a configuration example according to another embodiment of a sensor unit of a solid-state imaging apparatus to which the present disclosure is applied.

In the sensor unit 100 shown in FIG. 15, the pinning layer 114 is removed in portions of the silicon substrate 111 excluding those under the side wall unlike in the case of FIG. 2. For example, if the SiN film is etched and the pinning layer 114 is also etched when the second-layer side wall 116 is formed as described above with reference to FIG. 9, an unnecessary portion of the pinning layer 114 is removed as shown in FIG. 15.

Also in the case of FIG. 15, at the gate end, the pinning layer 114 is formed directly on the silicon substrate 111, thereby forming an area fixed to be filled with electron holes on a surface of the silicon substrate 111 at the gate end without injecting a p-type impurity ion. Therefore, there is no need to inject a p-type impurity ion into the gate end with extremely high accuracy.

As described above, also in the configuration shown in FIG. 15, it is possible to prevent generation of a dark current at the gate end because not only the p-type semiconductor area 122, which is formed by injecting a p-type impurity ion, but also the pinning area 123 is formed.

On the other hand, the pinning area 123 does not extend up to below the gate electrode 112, and therefore the transfer of a signal charge is not affected.

Alternatively, the pinning layer 114 under the side wall may be removed.

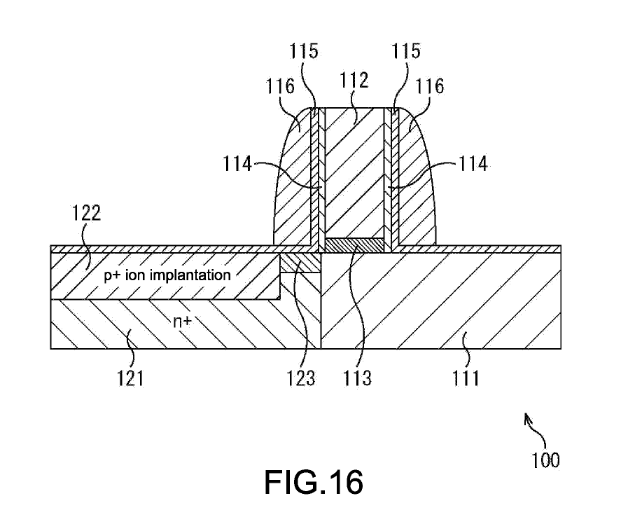

FIG. 16 is a diagram showing a configuration example according to still another embodiment of a sensor unit of a solid-state imaging apparatus to which the present disclosure is applied.

In the sensor unit 100 shown in FIG. 16, the pinning layer 114 is removed in portions excluding the side surface of the gate electrode 112 unlike in the case of FIG. 2 or FIG. 15. For example, if the pinning layer 114 is etched excluding a portion of the side surface of the gate electrode 112 after the pinning layer 114 is formed as described above with reference to FIG. 6, an unnecessary portion of the pinning layer 114 is removed as shown in FIG. 16.

It should be noted that in the configuration shown in FIG. 16, the pinning area 123 is formed in an extremely narrow area of the gate end.

Also in the case of FIG. 16, at the gate end, the pinning layer 114 is formed directly on the silicon substrate 111, thereby forming an area fixed to be filled with electron holes on a surface of the silicon substrate 111 at the gate end without injecting a p-type impurity ion. Therefore, there is no need to inject a p-type impurity ion into the gate end with extremely high accuracy.

As described above, also in the configuration shown in FIG. 16, it is possible to prevent generation of a dark current at the gate end because not only the p-type semiconductor area 122, which is formed by injecting a p-type impurity ion, but also the pinning area 123 is formed.

On the other hand, the pinning area 123 does not extend up to below the gate electrode 112, and therefore the transfer of a signal charge is not affected.

Alternatively, the pinning layer 114 may be formed on the entire surface of the silicon substrate 111.

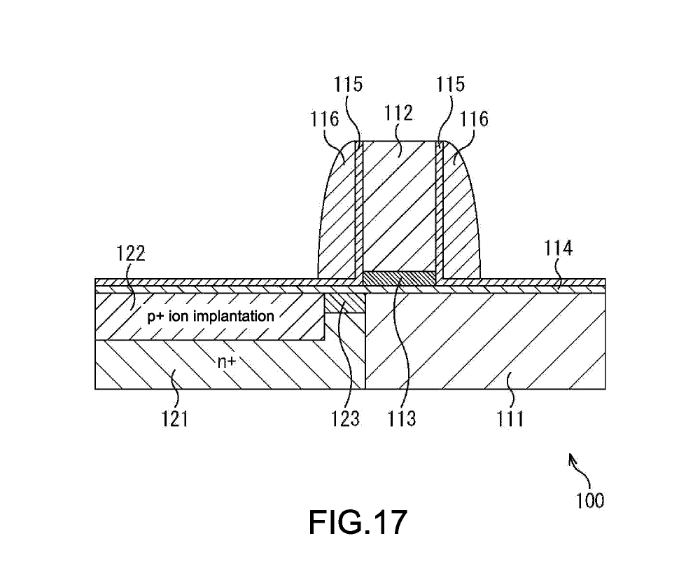

FIG. 17 is a diagram showing a configuration example according to still another embodiment of a sensor unit of a solid-state imaging apparatus to which the present disclosure is applied.

In the sensor unit 100 shown in FIG. 17, the pinning layer is not formed on the side surface of the gate electrode 112, and the pinning layer 114 is formed on the entire surface of the silicon substrate 111 unlike in the case of FIG. 2.

For example, if the pinning layer 114 is formed on the entire surface of the silicon substrate 111 and then the gate electrode 112 is formed after the separation area 131 and the photodiode area 132 are formed as described above with reference to FIG. 4, the sensor unit 100 shown in FIG. 17 can be formed.

In the configuration shown in FIG. 17, the gate insulating film 113 is not provided, and the pinning layer 114 is used instead of the gate insulating film.

As described above, the configuration shown in FIG. 17 is easily produced as compared to the configuration shown in FIG. 2, FIG. 15, or FIG. 16.

Moreover, by using the configuration shown in FIG. 17, areas of gate terminals of a reset transistor and a select transistor, which are not shown, can be reduced, and thus an area of a gate terminal of an amplifier transistor can be increased.

In an area constituting a unit pixel on the silicon substrate, the reset transistor, select transistor, and amplifier transistor, which are referred to so-called pixel transistors, are provided. Because the area constituting a unit pixel is extremely small, the sum of areas of the gate terminals of these pixel transistors is also limited. In order to improve output properties of a pixel signal, it is generally desirable to increase the area of the gate terminal of the amplifier transistor and to reduce the areas of the gate terminals of the reset transistor and select transistor.

However, if the length of the gate terminal is shortened to reduce the areas of the gate terminals of the reset transistor and select transistor, the aspect ratio of an element approaches one, and a short channel effect is caused. If a short channel effect is caused, a threshold value of drive voltage of a transistor is reduced, and it becomes difficult to control the drive of the transistor.

In the case where the configuration shown in FIG. 17 is used, the gate insulating film 113 is not provided but the pinning layer 114 is formed also under the gate terminals of the reset transistor and select transistor, which are formed on the silicon substrate 111. Accordingly, even if the lengths of the gate terminals of the reset transistor and select transistor are shortened, it is possible to prevent generation of a short channel effect.

Moreover, also in the configuration shown in FIG. 17, it is possible to prevent generation of a dark current at the gate end because not only the p-type semiconductor area 122, which is formed by injecting a p-type impurity ion, but also the pinning area 123 is formed.

It should be noted that in the case of the configuration shown in FIG. 17, the transfer properties of a signal charge are degraded as compared to the configuration shown in FIG. 2, FIG. 15, or FIG. 16, because the pinning area 123 extends below the gate electrode 112.

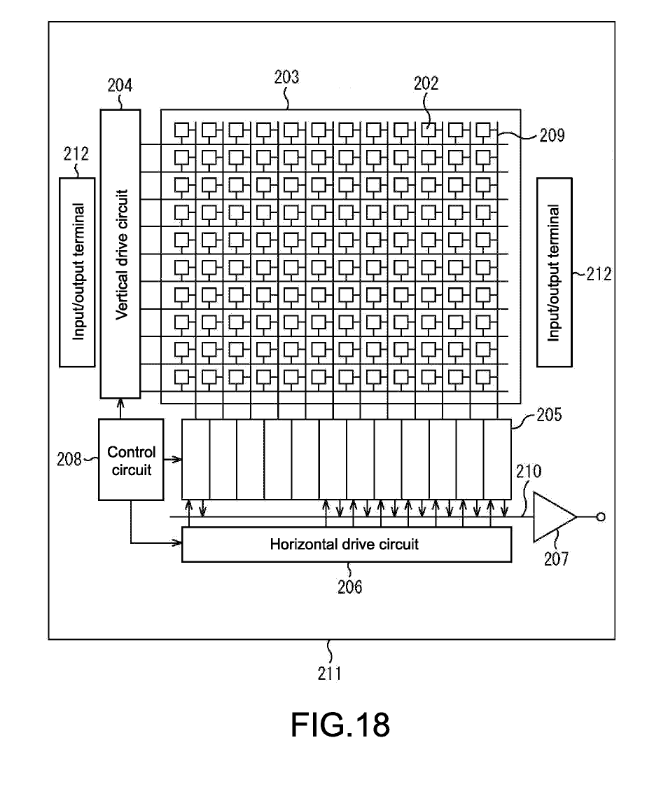

FIG. 18 is a diagram showing a schematic configuration of a solid-state imaging apparatus to which the present disclosure is applied. A solid-state imaging apparatus 200 is configured as, for example, a CMOS image sensor.

The solid-state imaging apparatus 200 shown in FIG. 18 includes a pixel area (so-called pixel array) 203 in which a plurality of pixels 202 including photoelectric conversion units are regularly arranged in a two-dimensional array form on a semiconductor substrate 211, e.g., silicon substrate, and a peripheral circuit unit.

Each of the pixels 202 can be configured as a unit pixel. Moreover, the pixel 202 can have a shared pixel structure.

The pixel 202 includes, for example, a sensor unit, which mainly includes a photodiode, and a plurality of pixel transistors (so-called MOS transistors). Each of the plurality of pixel transistors can include, for example, three transistors, i.e., a transfer transistor, a reset transistor, and an amplify transistor. Alternatively, the pixel transistor can include four transistors, i.e., a select transistor in addition the three transistors.

As a configuration of a sensor unit in the pixel 202, the configuration shown in FIG. 2, FIG. 15, FIG. 16, or FIG. 17 can be used.

The peripheral circuit unit includes a vertical drive circuit 204, a column signal processing circuit 205, a horizontal drive circuit 206, an output circuit 207, a control circuit 208, and the like.

The control circuit 208 receives an input clock and data for commanding an operation mode or the like, and outputs data such as internal information on a solid-state imaging apparatus. Specifically, the control circuit 208 generates a clock signal or a control signal, which is the standards of operations of the vertical drive circuit 204, the column signal processing circuit 205, the horizontal drive circuit 206, and the like, based on a vertical synchronous signal, a horizontal synchronous signal, and a master clock. Then, the control circuit 208 inputs these signals to the vertical drive circuit 204, the column signal processing circuit 205, the horizontal drive circuit 206, and the like.

The vertical drive circuit 204 includes, for example, a shift register, selects a pixel drive wiring, supplies a pulse for driving a pixel to the selected pixel drive wiring, and drives the pixel row by row. Specifically, the vertical drive circuit 204 selectively scans each pixel 202 in the pixel area 203 row by row in a vertical direction sequentially, and supplies, to the column signal processing circuit 205, a pixel signal based on a signal charge generated depending on the amount of received light in a photodiode, which is a photoelectric conversion unit of each pixel 202, through a vertical signal line 209.

The column signal processing circuits 205 are arranged for each column of the pixels 202, for example, and perform signal processing such as noise removal on signals output from a row of the pixels 202 for each pixel column. Specifically, the column signal processing circuit 205 performs signal processing such as CDS for removing unique fixed pattern noise of the pixel 202, signal amplification, and AD conversion. In an output stage of the column signal processing circuit 205, a horizontal select switch (not shown) is provided to be connected between the column signal processing circuit 205 and a horizontal signal line 210.

The horizontal drive circuit 206 includes, for example, a shift register, selects each of the column signal processing circuits 205 in series by sequentially outputting a horizontal scanning pulse, and causes each of the column signal processing circuits 205 to output a pixel signal to the horizontal signal line 210.

The output circuit 207 performs signal processing on a signal sequentially supplied from each of the column signal processing circuits 205 through the horizontal signal line 210, and then outputs the signal. For example, only buffering may be performed, or black level adjusting, column variation correction, various types of digital signal processing, and the like may be performed. An input/output terminal 212 exchanges signals with the outside.

As described above, because the solid-state imaging apparatus 200 includes the sensor unit 100 to which the present disclosure is applied in the pixel 202, it is possible to prevent generation of a dark current while maintaining transfer properties of a signal charge, and to capture an image with high quality. Furthermore, as described above, because the sensor unit 100 to which the present disclosure is applied is easily produced, it is possible to reduce the cost of the solid-state imaging apparatus 200.

Furthermore, the present disclosure is not limited to be applied to a solid-state imaging apparatus such as an image sensor. Specifically, the present disclosure can be applied to general electronic apparatuses using a solid-state imaging apparatus as an image capturing unit (photoelectric conversion unit), such as an imaging apparatus including a digital still camera and a video camera, a portable terminal apparatus having an imaging function, and a copier using a solid-state imaging apparatus as an image reading unit.

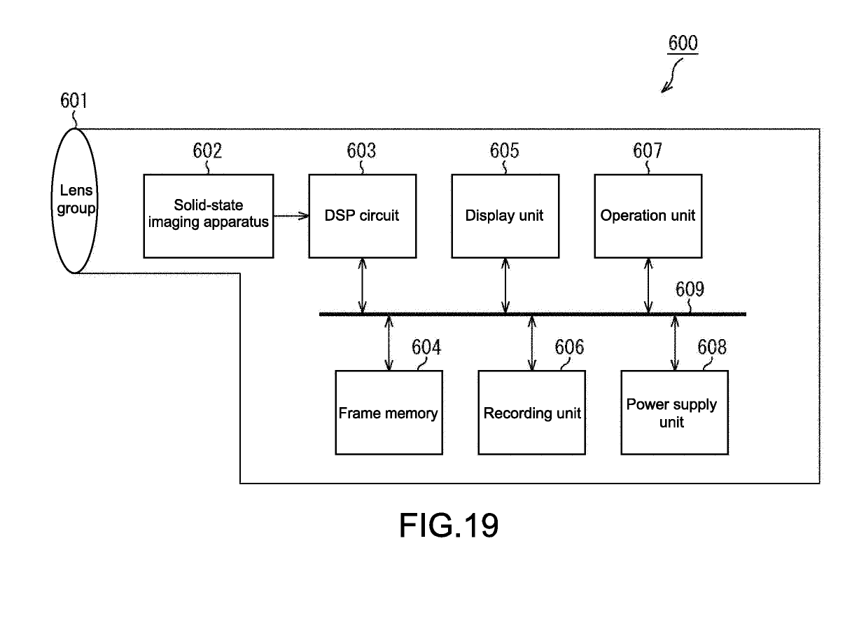

FIG. 19 is a block diagram showing a configuration example of a camera apparatus serving as an electronic apparatus to which the present disclosure is applied.

A camera apparatus 600 shown in FIG. 19 includes an optical unit 601 including a lens group and the like, a solid-state imaging apparatus (imaging device) 602 using the configuration of the above-mentioned pixel 202, and a DSP circuit 603 being a camera signal processing circuit. Moreover, the camera apparatus 600 includes a frame memory 604, a display unit 605, a recording unit 606, an operation unit 607, and a power supply unit 608. The DSP circuit 603, the frame memory 604, the display unit 605, the recording unit 606, the operation unit 607, and the power supply unit 608 are connected with each other via a bus line 609.

The optical unit 601 captures incident light (image light) from an object, and forms an image on an imaging surface of the solid-state imaging apparatus 602. The solid-state imaging apparatus 602 converts the amount of incident light imaged on the imaging surface by the optical unit 601 into an electric signal for each pixel, and outputs the signal as a pixel signal. As the solid-state imaging apparatus 602, the solid-state imaging apparatus 200 according to the embodiment described above with reference to FIG. 18 can be used.

The display unit 605 includes, for example, a panel display apparatus such as a liquid crystal panel and an organic EL (Electro Luminescence) panel, and displays a movie or a still image captured by the solid-state imaging apparatus 602. The recording unit 606 records the movie of the still image captured by the solid-state imaging apparatus 602 in a recording medium such as a video tape and a DVD (Digital Versatile Disk).

The operation unit 607 commands an operation for various functions of the camera apparatus 600 in response to a user's operation. The power supply unit 608 supplies various power supplies being operation power supplies of the DSP circuit 603, the frame memory 604, the display unit 605, the recording unit 606, and the operation unit 607 to the supply targets appropriately.

Moreover, the present disclosure is not limited to be applied to a solid-state imaging element, which detects distribution of the amount of incident visible light and captures it as an image, and can be applied to a solid-state imaging element, which captures the distribution of the incident amount of infrared rays, X-rays, particles, or the like as an image, and a general solid-state imaging element (physical amount distribution detection apparatus) in a broad sense, such as a fingerprint detection sensor, which detects distribution of another physical amount, e.g., pressure and capacitance, and captures it as an image.

Moreover, embodiments of the present disclosure are not limited to the above-mentioned embodiments and various modifications can be made without departing from the gist of the present disclosure.

It should be noted that the present disclosure may also take the following configurations.

(1) A solid-state imaging apparatus, including:

a charge accumulation unit configured to accumulate photoelectrically converted charges, the charge accumulation unit being formed on a silicon substrate;

a signal voltage detection unit configured to detect signal voltage corresponding to the charges accumulated in the charge accumulation unit, the signal voltage detection unit being formed on the silicon substrate;

a transfer transistor configured to transfer the charges accumulated in the charge accumulation unit to the signal voltage detection unit, the transfer transistor being formed on the silicon substrate; and

a pinning layer configured to pin a surface of the silicon substrate so that the surface is filled with electron holes, the pinning layer being formed directly on the silicon substrate at a gate end at which a gate electrode of the transfer transistor and the charge accumulation unit come into contact with each other on the silicon substrate.

(2) The solid-state imaging apparatus according to (1), in which

the charge accumulation unit is formed by having
an n-type semiconductor area formed in the silicon substrate so as to have a first depth, and
a p-type semiconductor area formed in the silicon substrate so as to have a second depth, the second depth being closer to the gate electrode than the first depth.
   (3) The solid-state imaging apparatus according to (2), in which

the n-type semiconductor area is formed by injecting an n-type impurity ion on the silicon substrate, and

the p-type semiconductor area is formed of the pinning layer.

(4) The solid-state imaging apparatus according to (3), in which

the n-type impurity ion is injected on the silicon substrate after the gate electrode is formed on the silicon substrate.

(5) The solid-state imaging apparatus according to (2), further including

a side wall that covers the gate electrode, in which

the p-type semiconductor area is formed by injecting an n-type impurity ion on the silicon substrate after the side wall is formed on the silicon substrate.

(6) The solid-state imaging apparatus according to any one of (1) to (5), in which

the pinning layer includes one of a hafnium (Hf)-based insulating film and an aluminum (Al)-based insulating film.

(7) The solid-state imaging apparatus according to any one of (1) to (6), in which

the pinning layer is formed directly on the silicon substrate at the gate and on a side surface of the gate electrode.

(8) The solid-state imaging apparatus according to any one of (1) to (7), further including

a side wall that covers the gate electrode, wherein

the pinning layer is formed directly on the silicon substrate and on a side surface of the gate electrode, under the side wall having the gate end.

(9) An electronic apparatus, including

a solid-state imaging apparatus, including
a charge accumulation unit configured to accumulate photoelectrically converted charges, the charge accumulation unit being formed on a silicon substrate;
a signal voltage detection unit configured to detect signal voltage corresponding to the charges accumulated in the charge accumulation unit, the signal voltage detection unit being formed on the silicon substrate;
a transfer transistor configured to transfer the charges accumulated in the charge accumulation unit to the signal voltage detection unit, the transfer transistor being formed on the silicon substrate; and
a pinning layer configured to pin a surface of the silicon substrate so that the surface is filled with electron holes, the pinning layer being formed directly on the silicon substrate at a gate end at which a gate electrode of the transfer transistor and the charge accumulation unit come into contact with each other on the silicon substrate.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state imaging apparatus, comprising:
a charge accumulation unit configured to accumulate photoelectrically converted charges, the charge accumulation unit being formed on a silicon substrate;
a signal voltage detection unit configured to detect signal voltage corresponding to the charges accumulated in the charge accumulation unit, the signal voltage detection unit being formed on the silicon substrate;
a transfer transistor configured to transfer the charges accumulated in the charge accumulation unit to the signal voltage detection unit, the transfer transistor being formed on the silicon substrate; and
a pinning layer configured to pin a surface of the silicon substrate so that the surface is filled with electron holes, the pinning layer being formed directly on the silicon substrate at a gate end at which a gate electrode of the transfer transistor and the charge accumulation unit come into contact with each other on the silicon substrate.

2. The solid-state imaging apparatus according to claim 1, wherein
the charge accumulation unit is formed by having
an n-type semiconductor area formed in the silicon substrate so as to have a first depth, and
a p-type semiconductor area formed in the silicon substrate so as to have a second depth, the second depth being closer to the gate electrode than the first depth.

3. The solid-state imaging apparatus according to claim 2, wherein
the n-type semiconductor area is formed by injecting an n-type impurity ion on the silicon substrate, and
the p-type semiconductor area is formed of the pinning layer.

4. The solid-state imaging apparatus according to claim 3, wherein
the n-type impurity ion is injected on the silicon substrate after the gate electrode is formed on the silicon substrate.

5. The solid-state imaging apparatus according to claim 2, further comprising
a side wall that covers the gate electrode, wherein
the p-type semiconductor area is formed by injecting an n-type impurity ion on the silicon substrate after the side wall is formed on the silicon substrate.

6. The solid-state imaging apparatus according to claim 1, wherein
the pinning layer includes one of a hafnium (Hf)-based insulating film and an aluminum (Al)-based insulating film.

7. The solid-state imaging apparatus according to claim 1, wherein
the pinning layer is formed directly on the silicon substrate at the gate end and on a side surface of the gate electrode.

8. The solid-state imaging apparatus according to claim 1, further comprising
a side wall that covers the gate electrode, wherein
the pinning layer is formed directly on the silicon substrate and on a side surface of the gate electrode, under the side wall having the gate end.

9. An electronic apparatus, comprising
a solid-state imaging apparatus, including
a charge accumulation unit configured to accumulate photoelectrically converted charges, the charge accumulation unit being formed on a silicon substrate;
a signal voltage detection unit configured to detect signal voltage corresponding to the charges accumulated in the charge accumulation unit, the signal voltage detection unit being formed on the silicon substrate;
a transfer transistor configured to transfer the charges accumulated in the charge accumulation unit to the signal voltage detection unit, the transfer transistor being formed on the silicon substrate; and
a pinning layer configured to pin a surface of the silicon substrate so that the surface is filled with electron holes, the pinning layer being formed directly on the silicon substrate at a gate end at which a gate electrode of the transfer transistor and the charge accumulation unit come into contact with each other on the silicon substrate.
